(19) United States
(12) Patent Application Publication
(10) Pub. No.: US 2012/0119749 A1
(43) Pub. Date: May 17, 2012

(54) CHARGE STATE DETECTION CIRCUIT, BATTERY POWER SUPPLY DEVICE, AND BATTERY INFORMATION MONITORING DEVICE

(76) Inventor: Takuma Iida, Kanagawa (JP)

(21) Appl. No.: 13/381,618

(22) PCT Filed: Jan. 27, 2011
(86) PCT No.: PCT/JP11/00440

§ 371 Date: Dec. 29, 2011

(30) Foreign Application Priority Data
Mar. 26, 2010 (JP) 2010-073279

(51) Int. Cl. G01R 31/36

(52) U.S. Cl. 324/435; 324/426

(57) ABSTRACT

A charge state detection circuit, which detects a state of charge of a battery block in which are parallel-connected a plurality of series circuits of a secondary battery and a cutoff element which assumes a cutoff state of cutting off the charge/discharge path of the secondary battery and a conducting state different from the cutoff state, the charge state detection circuit comprising: an effective battery number detection portion which detects, as the number of effective batteries, the number of cutoff elements in the conducting state from among the plurality of cutoff elements included in the battery block; a capacity information generation portion which, based on the number of effective batteries, generates capacity information related to actual full charge capacity, which is the actual full charge capacity of the battery block; a total current detection portion, which detects as a total current value a current flowing in the entire battery block; an electricity quantity calculation portion, which calculates, as a stored electricity quantity, an electricity quantity stored in the battery block, by integrating the total current value; and a charge state detection portion, which, based on the capacity information and the stored electricity quantity, detects a state of charge, which is a ratio of the stored electricity quantity to the actual full charge capacity.

### TECHNICAL FIELD

This invention relates to a charge state detection circuit which detects the charging state of a battery block, in which a plurality of secondary batteries are connected in parallel, a battery power supply device which uses this circuit, and a battery information monitoring device which monitors information relating to such a battery block.

### BACKGROUND ART

In a battery power supply device of the prior art which supplies power to a load circuit using secondary batteries, in order to secure the output current required by the load circuit, a battery block in which a plurality of secondary batteries are connected in parallel is widely used.

In such a battery power supply device, when an overcurrent, overheating, or another abnormality occurs in a portion of the secondary batteries in a battery block, if charging and discharging of the battery block are performed in the same manner as usual, there is the concern that the secondary batteries may be caused to degrade.

Hence techniques are known in which, when an abnormality, such as for example drop-out, a broken line, or another abnormality is detected in a portion of the secondary batteries included in a battery block, a switching element or protective element is turned off, to prohibit charging and discharging of the entire battery power supply device (see for example Patent Documents 1 and 2).

However, when an abnormality occurs in a portion of the secondary batteries included in a battery block as in the above-described techniques, there are cases in which prohibiting charging and discharging of the entire battery power supply device is undesirable.

For example, in a hybrid electric vehicle (HEV) using an engine and a motor, when traveling using the motor, a discharge current from a battery power supply device drives the motor, and the battery block is discharged. On the other hand, when the output from the engine is large compared with the power necessary for vehicle traveling, the excess engine output is used to drive a generator and the battery block of the battery power supply device is charged. Further, during braking and deceleration of the HEV, the motor is used as a generator, and the recovered electric power is used to charge the battery block of the battery power supply device.

Hence in applications such as HEVs, if charging/discharging of a battery power supply device is prohibited when an abnormality occurs in a portion of the secondary batteries included in a battery block, the vehicle may halt during travel, or the battery power supply device may no longer be able to absorb the power generated by the generator and regenerated power, so that there are concerns that overvoltages may occur.

Consequently, when an abnormality occurs in a portion of the secondary batteries included in a battery block, it is necessary to detach only the secondary batteries in which the abnormality has occurred, and continue to use the remaining, normal secondary batteries. However, the characteristics of a battery block in which a portion of secondary batteries have been cut off are changed from those prior to the cutting-off of the secondary batteries, and so without taking further measures, it is difficult to ascertain the state of charge of the battery block.

### CITATION LIST

### Patent Literature

Patent Document 1: Japanese Patent Application Laid-open No. 2008-27658

Patent Document 2: Japanese Patent Application Laid-open No. 2008-71568

### SUMMARY OF THE INVENTION

An object of this invention is to provide a charge state detection circuit which can ascertain the state of charge of a battery block even when a portion of the secondary batteries included in the battery block are cut off, battery power supply device using such a circuit, and battery information monitoring device which monitors information relating to a battery block.

The charge state detection circuit according to one aspect of the invention has: an effective battery number detection portion which, for a battery block in which are connected in parallel a plurality of series circuits of a secondary battery and a cutoff element which can assume a cutoff state of cutting off the charge/discharge path of the secondary battery and a conducting state different from the cutoff state, detects, as the number of effective batteries, the number of cutoff elements in the conducting state from among the plurality of cutoff elements included in the battery block; a capacity information generation portion which, based on the number of effective batteries, generates capacity information related to the actual full charge capacity, which is the actual full charge capacity of the battery block; a total current detection portion, which detects the total current value indicating the current flowing in the battery block; an electricity quantity calculation portion, which calculates as a stored electricity quantity an electricity quantity stored in the battery block, by integrating the total current value; and a charge state detection portion, which, based on the capacity information and the stored electricity quantity, detects the state of charge, which is a ratio of the stored electricity quantity to the actual full charge capacity.

Further, the battery power supply device according to one aspect of the invention comprises the above-described charge state detection circuit and the abovementioned battery block.

Further, the battery information monitoring device according to one aspect of the invention comprises a reception portion which receives value information communicated from the above-described charge state detection circuit; a ranking portion which, based on value information received by the reception portion, ranks the value of the battery block; and a display portion, which displays the rank of the ranked value.

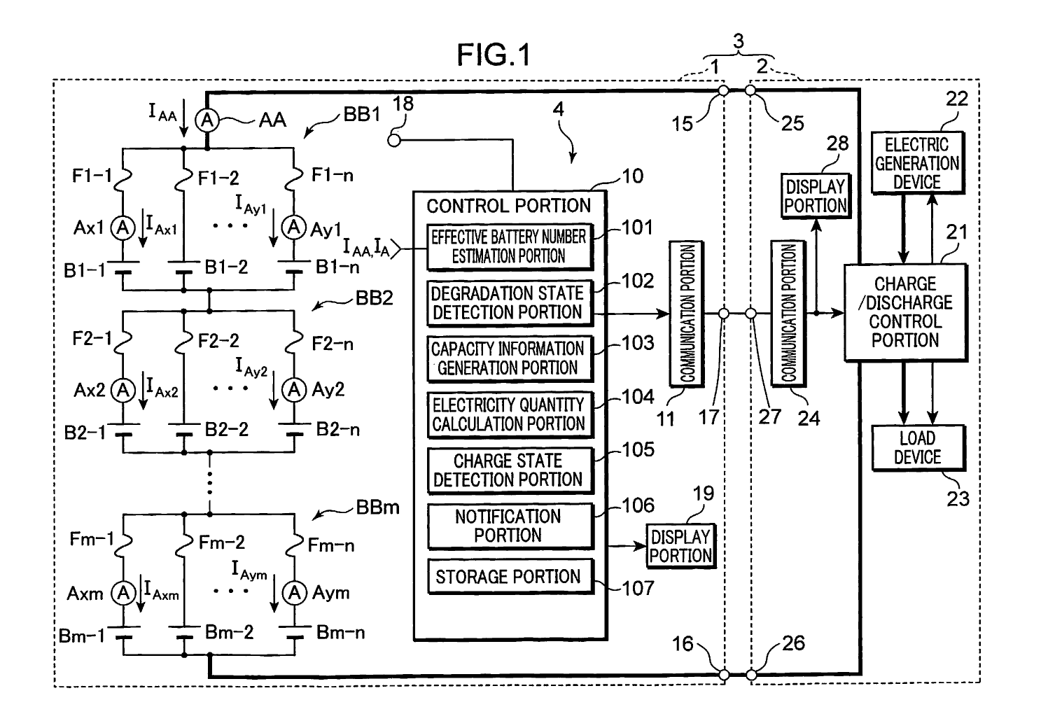

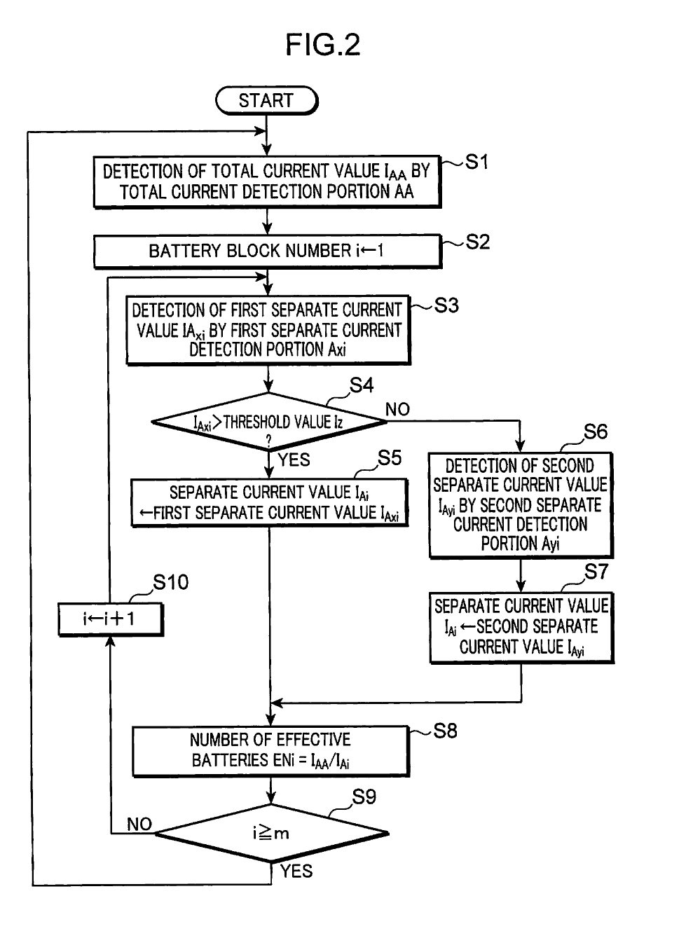

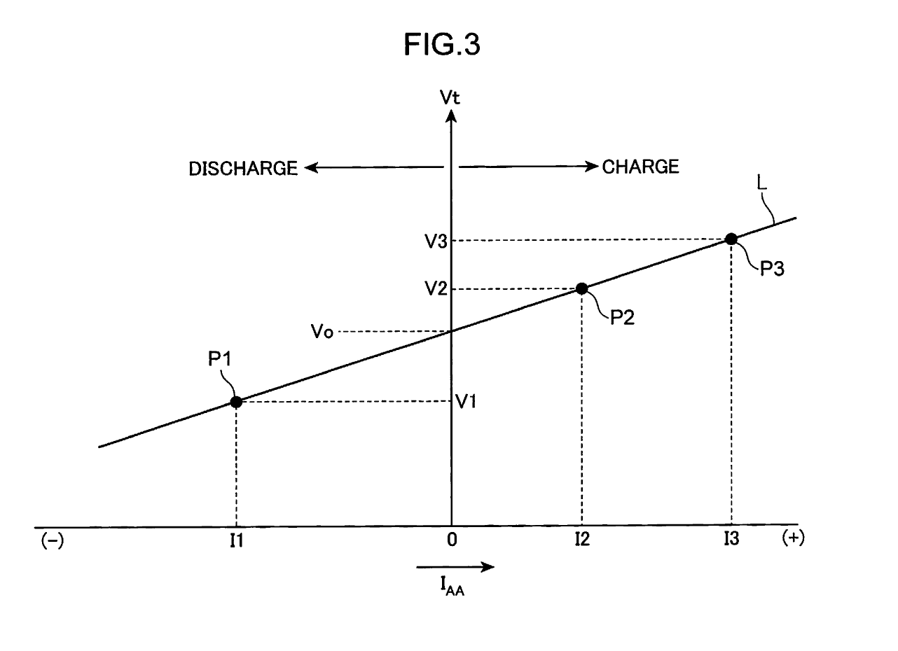

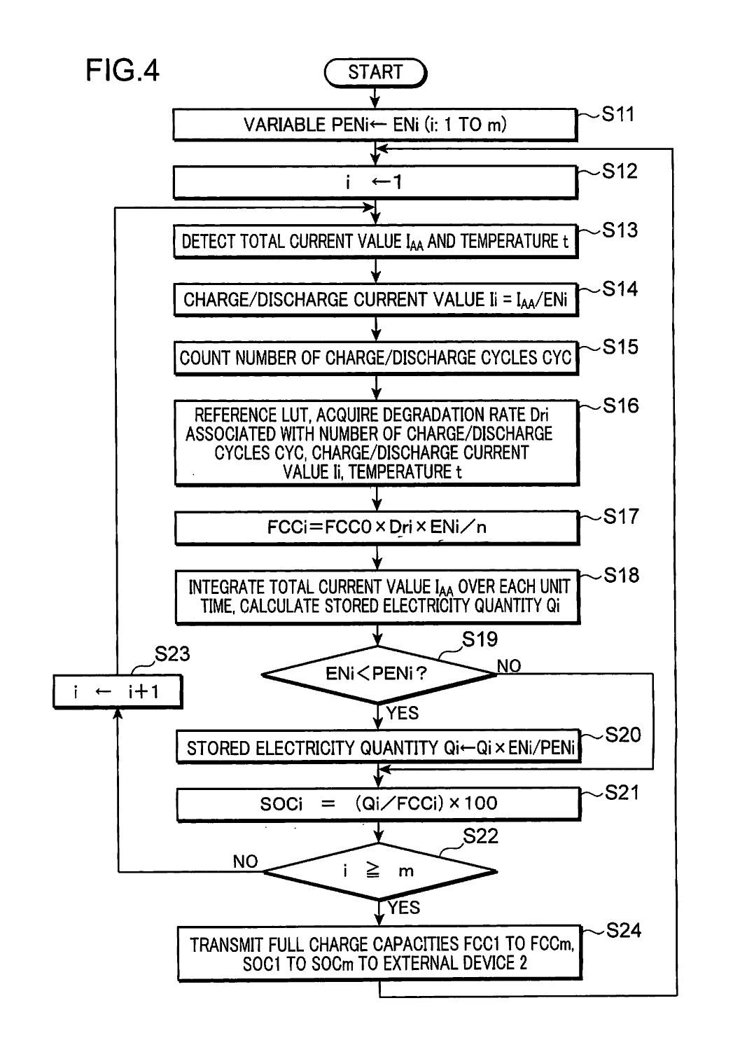

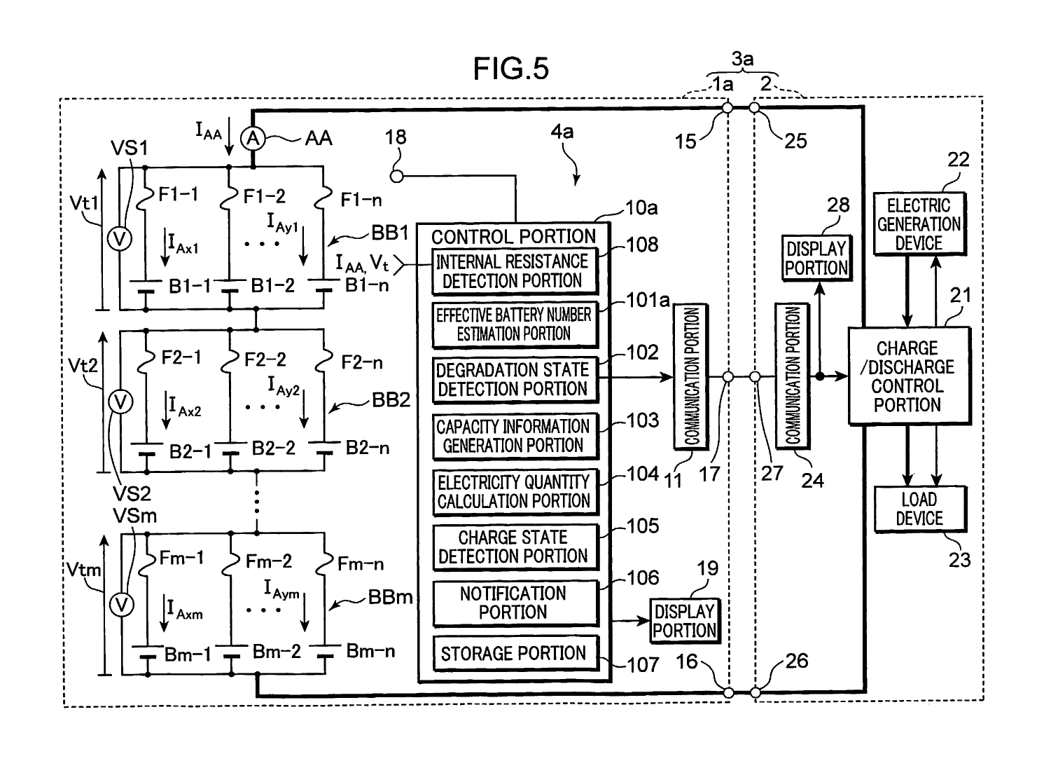

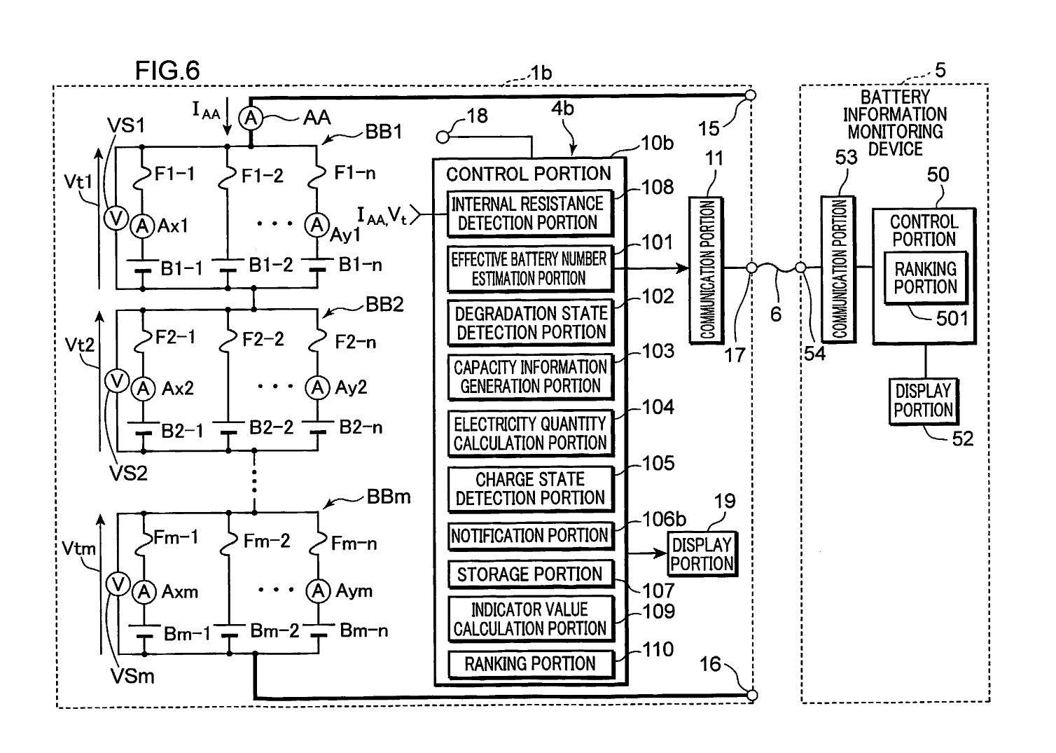

### BRIEF DESCRIPTION OF THE DRAWINGS

[FIG. 1] FIG. 1 is a block diagram showing one example of a battery power supply device using the charge state detection circuit of a first embodiment of the invention, and a battery power supply system comprising the battery power supply device.

[FIG. 2] FIG. 2 is a flowchart showing one example of operation to calculate the number of effective batteries EN of the battery power supply device shown in FIG. 1.

[FIG. 3] FIG. 3 is an explanatory diagram used to explain one example of a method of estimating the internal resistance value of a battery block.

[FIG. 4] FIG. 4 is a flowchart showing one example of operation to calculate SOC1 to SOCm and the full charge capacities FCC1 to FCCm by the charge state detection circuit shown in FIG. 1.

[FIG. 5] FIG. 5 is a block diagram showing a modified example of the charge state detection circuit shown in FIG. 1.

[FIG. 6] FIG. 6 is a block diagram showing one example of the configuration of the battery power supply device and battery information monitoring device of a second embodiment of the invention.

### DESCRIPTION OF EMBODIMENTS

Below, embodiments of the invention are explained based on the drawings. In each drawing, portions assigned the same symbols are the same, and explanations thereof are omitted.

### First Embodiment

FIG. 1 is a block diagram showing one example of a battery power supply device using the charge state detection circuit of a first embodiment of the invention, and a battery power supply system comprising the battery power supply device.

The battery power supply system 3 shown in FIG. 1 is configured by combining a battery power supply device 1 and an external device 2. The battery power supply device 1 shown in FIG. 1 comprises m (for example, 10) battery blocks BB1 to BBm, a total current detection portion AA, a control portion 10, a communication portion 11, a temperature sensor 18, connection terminals 15, 16, 17, and a display portion 19.

And, the portions of the battery power supply device 1 excluding the battery blocks BB1 to BBm form a charge state detection circuit 4.

The m battery blocks BB1 to BBm are connected in series. And, the positive electrode of the series circuits of the battery blocks BB1 to BBm, that is, the positive electrode of the battery block BB1, is connected via the total current detection portion AA to the connection terminal 15. Further, the negative electrode of the series circuit of battery blocks BB1 to BBm, that is, the negative electrode of the battery block BBm, is connected to the connection terminal 16. The connection terminal 17 is connected to the communication portion 11.

The battery blocks BB1 to BBm are interconnected by a single conducting line in FIG. 1. However, the battery blocks BB1 to BBm may be interconnected by a plurality of conducting lines.

The temperature sensor 18 is configured using for example a thermistor, thermocouple, or other heat-sensing element, and an analog/digital converter or similar. The temperature sensor 18 is for example connected to the battery blocks BB1 to BBm, or is disposed in proximity thereto, and outputs a signal indicating the temperature t of the battery blocks BB1 to BBm to the control portion 10.

The external device 2 shown in FIG. 1 comprises a charge/discharge control portion 21, electric generation device 22 (current provision portion), load device 23 (load circuit), communication portion 24, display portion 28, and connection terminals 25, 26, 27. The connection terminals 25 and 26 are connected to the charge/discharge control portion 21, and the connection terminal 27 is connected via the communication portion 24 to the charge/discharge control portion 21. The electric generation device 22 and load device 23 are connected to the charge/discharge control portion 21.

The external device 2 may for example be an HEV (Hybrid Electric Vehicle) or EV (Electric Vehicle), or may be an electric generation system such as a photovoltaic power generation system, or may be a storage system for power adjustment. Further, the external device 2 may be equipment not comprising an electric generation system 22, such as for example the main unit of a portable personal computer or other battery-driven device.

When the external device 2 is an HEV or EV, the display portion 28 may be an instrument panel.

And, when a battery power supply device 1 and external device 2 are combined, the connection terminals 15, 16, 17 are connected to the connection terminals 25, 26, 27 respectively.

On the surfaces of the battery blocks BB1 to BBm is visibly displayed, for example by means of printing or labels, identification information to identify each of the battery blocks. As identification information, for example a number i, described below, is used. An example is described in which a plurality of battery blocks are comprised, but a single battery block may be used.

The battery blocks BB1 to BBm are similarly configured, and so the configuration of the ith battery block BBi is explained as representative of the battery blocks BB1 to BBm.

The battery block BBi is configured by series-connecting n (for example, 20) series circuits of a fuse F, as one example of a cutoff element, and a secondary battery B. Below, in a battery block BBi shown in FIG. 1, the fuse F and secondary battery B included in each series circuit are denoted by a number j, assigned in order from the left, as fuses Fi-j and secondary batteries Bi-j.

The first series circuit in the battery block BBi is configured by series-connecting the fuse Fi-1, a first separate current detection portion Axi, and the secondary battery Bi-1. Series circuits for which the number j is 2 to (n-1) in the battery block BBi are configured by series-connecting the fuse Fi-j and secondary battery Bi-j. The nth series circuit in the battery block BBi is configured by series-connecting the fuse Fi-n, a second separate current detection portion Ayi, and the secondary battery Bi-n.

Below, the battery blocks BB1 to BBm are collectively denoted as the battery blocks BB, the fuses Fi-1 to Fi-n (where i is the battery block number, from 1 to m) are collectively denoted as the fuses F, the secondary batteries Bi-1 to Bi-n (where is the battery block number, 1 to m) are collectively denoted as the secondary batteries B, the first separate current detection portions Ax1 to Axm are collectively denoted as the first separate current detection portions Ax, and the second separate current detection portions Ay1 to Aym are collectively denoted as the second separate current detection portions Ay.

In FIG. 1, an example is shown in which the first separate current detection portion Axi is included in the first series circuit, and the second separate current detection portion Ayi is included in the nth series circuit; but the first and second separate current detection portions may be included in any of the series circuits. Further, the first and second separate current detection portions need only be connected in series with the fuses F and secondary batteries B, and configurations are not limited to examples in which these portions are interposed between fuses F and secondary batteries B. Further, an example was presented in which two separate current detection portions are provided in each of the battery blocks BB; but a configuration may be employed in which second separate current detection portions are not comprised, or three or more separate current detection portions may be provided.

The total current detection portion AA, first separate current detection portions Ax, and second separate current detection portions Ay are for example configured using a Hall element, a shunt resistor, a current transformer, or similar. Because a voltage loss occurs in a shunt resistor and current transformer, if used as first separate current detection portions Ax and second separate current detection portions Ay connected only to a portion of the secondary batteries B parallel-connected within the battery blocks BB, the voltages (currents) applied to the secondary batteries B become unbalanced.

On the other hand, in a Hall element the occurrence of voltage loss is suppressed. Hence when Hall elements are used as the first separate current detection portions Ax and second separate current detection portions Ay, concerns about imbalance of the voltages (currents) applied to the secondary batteries B can be alleviated, and so the use of Hall elements is preferable.

And, the control portion 10 acquires the values of currents flowing in the total current detection portion AA, first separate current detection portions Ax, and second separate current detection portions Ay by converting the voltages generated by the total current detection portion AA, first separate current detection portions Ax, and second separate current detection portions Ay, that is, voltages indicating the detected current values, into digital values using for example an analog/digital converter.

By this means, the total current detection portion AA detects the total current value I_{AA} flowing in the battery blocks BB1 to BBm, the first separate current detection portions Axi detect the first separate currents I_{Axi} flowing in the first series circuits on the left in the battery blocks BBi, and the second separate current detection portions Ayi detect the second separate currents I_{Ayi} flowing in the nth series circuit from the left in the battery blocks BBi.

The total current detection portion AA, first separate current detection portions Ax, and second separate current detection portions Ay are configured such that values of currents flowing in the direction to charge the secondary batteries B are for example represented by positive values, and the values of currents flowing in the direction to discharge the secondary batteries B are represented by negative values.

As the secondary batteries B, for example lithium ion secondary batteries, nickel metal hydride secondary batteries, or various other secondary batteries can be used. The secondary batteries B may be single batteries. Or, the secondary batteries B may be battery modules, in which a plurality of single batteries are connected in series or in parallel. Or, secondary batteries B may be battery modules in which a plurality of single batteries are connected by a connection method which combines series connections and parallel connections.

Fuses F are configured so as to be able to assume conducting states and cutoff states. Fuses F are configured such that, for example, in a case in which the secondary battery B which is series-connected to the fuse F undergoes a short circuit, or some other abnormality occurs, the cutoff state is entered, and current flowing to the secondary battery B is cut off. As cutoff elements, in place of fuses F, for example a member with a PTC (Positive Temperature Coefficient), or some other protective elements may be used.

The communication portions 11 and 24 are communication interface circuits. By connecting the connection terminal 17 and the connection terminal 27, data can be exchanged between the communication portions 11 and 24. The control portion 10 and the charge/discharge control portion 21 can mutually exchange data via the communication portions 11 and 24.

The display portions 19 and 28 are for example liquid crystal displays or other display devices.

The control portion 10 is configured comprising, for example, a CPU (Central Processing Unit) which executes prescribed computation processing; ROM (Read Only Memory) which is a storage portion in which a prescribed control program is stored; RAM (Random Access Memory) which is a storage portion in which data is temporarily stored; an analog/digital converter; a storage portion 107; and peripheral circuitry thereof, and similar. And, by for example executing the control program stored in ROM, the control portion 10 functions as an effective battery number estimation portion 101, degradation state detection portion 102, capacity information generation portion 103, electricity quantity calculation portion 104, charge state detection portion 105, and notification portion 106.

The storage portion 107 is configured using for example nonvolatile EEPROM (Electrically Erasable and Programmable Read Only Memory). The storage portion 107 stores at least one among the degradation rates Dr1 to Drm, effective battery quantities EN1 to ENm, full charge capacities FCC1 to FCCm, States of Health SOH1 to SOHm, and States of Charge SOC1 to SOCm, described below. The full charge capacities FCC1 to FCCm are equivalent to one example of actual full charge capacities, actual full charge capacities are equivalent to one example of capacity information, and the SOH1 to SOHm are equivalent to another example of capacity information.

Here, by means of the total current detection portion AA, first separate current detection portions Axi, second separate current detection portions Ayi, and effective battery number estimation portion 101, an example of an effective battery number detection portion is configured.

For the battery blocks BBi (i: 1 to m), the effective battery number estimation portion 101 uses the first separate current values I_{Axi} detected by the first separate current detection portions Axi as separate current values I_{Ai}, and divides the total current value I_{AA} detected by the total current detection portion AA by the separate current values I_{Ai}, taking the values rounded to for example the fourth place below the decimal point to calculate values of the effective battery quantities ENi (i: 1 to m). The number of effective batteries ENi is equivalent to the number of fuses, among the fuses Fi-1 to Fi-n in a battery block BBi, which have not undergone cutoff (been blown).

Here, “the fuse F has not undergone cutoff” means “the fuse F is in the conducting state”.

Further, when a first separate current value I_{Axi} detected by a first separate current detection portion Axi is effectively zero, the effective battery number estimation portion 101 uses the second separate current value I_{Ayi} detected by the second separate current detection portion Ayi as the separate current value I_{Ai}. And, the effective battery number estimation portion 101 calculates the quotient obtained by dividing the total current value I_{AA} detected by the total current detection portion AA by the separate current value I_{Ai}, rounded down to for example four places below the decimal point, as an number of effective batteries ENi indicating the number of fuses among the fuses Fi-1 to Fi-n in the battery block BBi which are in the conducting state.

“Effectively zero” means not only exactly zero, but also includes currents in the range of the magnitude of detection errors by the first separate current detection portion Axi which can be regarded as zero.

The degradation state detection portion 102 detects the degradation rate Dr as an example of degradation information indicating the state of degradation of secondary batteries B. The degradation rate Dr is the ratio of the full charge capacity of secondary batteries B at the present time, that is, after degradation, to the full charge capacity of the secondary batteries B in the initial state.

Specifically, for example, the degradation state detection portion 102 acquires the degradation rate Dr as follows. Major factors in degradation of the secondary batteries B include cycle degradation due to the number of charge/discharge cycles of the secondary batteries B, degradation due to the charge/discharge current flowing in the secondary batteries B, and degradation which occurs depending on the temperature t of the secondary batteries B.

That is, as the number of charge/discharge cycles of the secondary batteries B increases, degradation advances and the degradation rate Dr is reduced; the larger the charge/discharge current, the more degradation advances, so that the degradation rate Dr is reduced; and the higher the temperature t, the more degradation advances, so that the degradation rate Dr is reduced.

Hence degradation rates Dr corresponding to a combination of for example the number of charge/discharge cycles, charge/discharge current values, and temperatures t are determined experimentally in advance. And, numbers of charge/discharge cycles, charge/discharge current values, temperatures t, and degradation rates Dr are stored in association in a LUT (Look Up Table) in ROM.

And, the degradation state detection portion 102 monitors the total current value I_{AA} detected by the total current detection portion AA, for example, counting either the number of times the total current value I_{AA} changes from positive to negative, or the number of times the total current value I_{AA} changes from negative to positive, and detects this count value as the number of charge/discharge cycles of the secondary batteries B.

Further, the degradation state detection portion 102 divides the total current value I_{AA} detected by the total current detection portion AA by the number of effective batteries ENi, for example, to calculate the charge/discharge current Ii flowing in one secondary battery B included in a battery block BBi. Further, the degradation state detection portion 102 acquires the temperature t detected by the temperature sensor 18.

And, the degradation state detection portion 102 references the LUT stored in ROM, and acquires, as the degradation rate Dri (i: 1 to m) of secondary batteries B included in a battery block BBi, the degradation rate Dr corresponding to the number of charge/discharge cycles, charge/discharge current value Ii, and temperature t, obtained as described above.

The method of detection of the degradation rate Dr is not limited to this method, and various other methods can be used.

For example, there is a correlation between the SOC (State of Charge) of secondary batteries B and the terminal voltage; when the secondary batteries B are charged and the SOC increases, the terminal voltage rises. Here, as degradation of the secondary batteries B advances and the full charge capacity is reduced, compared with prior to degradation, if the charged electricity quantity is the same, the increase in SOC is greater after degradation. And if the SOC increase is greater, the rise in terminal voltage is also higher.

Hence the degradation rate Dr corresponding to the combination of the charge/discharge electricity quantity and rise in terminal voltage is determined experimentally in advance, for example, and charge/discharge electricity quantities, rises in terminal voltage, and degradation rates Dr are stored in association in a LUT in ROM.

And, the degradation state detection portion 102 may be configured such that, when the secondary batteries B are charged, the stored degradation rate Dr corresponding to the charging electricity quantity and rise amount is acquired using the above-described LUT from the rise in terminal voltage for the charging electricity quantity, to detect the degradation rate Dr.

From the effective battery quantities ENi (i: 1 to m) estimated by the effective battery number estimation portion 101, and the degradation rates Dri (i: 1 to m) detected by the degradation state detection portion 102, the capacity information generation portion 103 uses the following equation (1) to calculate, as capacity information, the present full charge capacities FCCi (i: 1 to m) of each of the battery blocks BBi (i: 1 to m). The present full charge capacities FCCi are the actual full charge capacities of each of the battery blocks BBi.

FCCi=FCC0×Dri×ENi/n (1)

Here, the full charge capacities of each of the battery blocks BB in the initial state without degradation, when all the fuses F included in the battery blocks BB are in the conducting state, are taken to be the initial full charge capacities FCC0, and the number of series circuits included in one battery block BB is taken to be n.

The factor (Dri×ENi/n) included in equation (1) is equal to the ratio of the present (actual) full charge capacity to the initial full charge capacity of a battery block BBi, and is called the SOH (State of Health). The SOH is equivalent to one example of a value indicator. Below, the SOH of a battery block BBi is called SOHi.

The capacity information generation portion 103 may also calculate the initial full charge capacity FCC0 by multiplying the full charge capacity of one secondary battery B, in the initial state and not yet degraded, by the number n.

Further, the capacity information generation portion 103 may be configured so as to calculate, as capacity information, Dri×ENi/n, that is, SOHi, as the value obtained by multiplying the effective battery ratio ENi/n by the degradation rate Dri detected by the degradation state detection portion 102. The effective battery ratio (ENi/n) is the ratio of the number of effective batteries ENi to the number n of series circuits included in one battery block BB. The effective battery rate (ENi/n) corresponds to one example of capacity information.

In this case, the charge state detection portion 105 described below may calculate the full charge capacity FCCi from the SOHi (i: 1 to m) of the battery block BBi obtained from the capacity information generation portion 103, and the following equation (2).

FCCi=FCC0×SOHi (2)

Further, a degradation state detection portion 102 may not be comprised, and instead of equation (1), the following equation (3) may be used. Further a degradation state detection portion 102 may not be comprised, and the capacity information generation portion 103 may use ENi/n instead of the SOHi in equation (2).

FCCi=FCC0×ENi/n (3)

Even in the case of a configuration not comprising a degradation state detection portion 102, although the precision of calculation of the full charge capacity FCCi is reduced compared with a case in which a degradation state detection portion 102 is used, the configuration of the charge state detection circuit 4 can be simplified.

The electricity quantity calculation portion 104 integrates the total current value I_{AA} detected by the total current detection portion AA, for example over each time unit, and calculates the stored electricity quantities Q1 to Qm which are electricity quantities charging the battery blocks BB1 to BBm respectively.

The battery blocks BB1 to BBm are series-connected, so that currents flowing in the battery blocks BB1 to BBm are all equal to the total current value I_{AA}. Hence the charging electricity quantities charging the battery blocks BB1 to BBm are equal. However, in a battery block in which cutoff of a fuse F occurs and the number of effective batteries EN is reduced, the stored electricity quantity of the battery block is reduced by the stored electricity quantity which had charged the detached secondary battery B.

Hence for the battery blocks BBi (i: 1 to m), when the number of effective batteries ENi (i: 1 to m) detected by the effective battery number estimation portion 101 is reduced, the electricity quantity calculation portion 104 calculates the product of the ratio of the number of effective batteries ENi after this reduction to the number of effective batteries ENi before the reduction, and the stored electricity quantity Qi, as the new stored electricity quantity Qi.

Based on the full charge capacities FCCi (i: 1 to m) generated by the capacity information generation portion 103, and the stored electricity quantities Qi calculated by the electricity quantity calculation portion 104, the charge state detection portion 105 uses the following equation (4) to calculate the SOCi (i: 1 to m) of the battery blocks BBi (i: 1 to m), representing as a percentage the ratio of the full charge capacity FCCi to the stored electricity quantity Qi.

SOCi=(Qi/FCCi)×100 (%) (4)

The notification portion 106 transmits the values of SOC1 to m calculated by the charge state detection portion 105, and the values of the full charge capacities FCC1 to m calculated by the capacity information generation portion 103, to the charge/discharge control portion 21 via the communication portions 11, 24.

Further, the notification portion 106 causes the display portion 19 to display information stored in the storage portion 107, such as for example degradation rates Dr1 to Drm, effective battery quantities EN1 to ENm, full charge capacities FCC1 to FCCm, SOH1 to SOHm, and SOC1 to SOCm. Further, the notification portion 106, by causing this information to be transmitted to the display portion 28 by the communication portions 11, 24, causes this information to be displayed by the display portion 28.

Next, the external device 2 is explained. The electric generation device 22 is for example a photovoltaic electric generation device (solar cells), or an electric generator or similar driven by for example such natural energy sources as wind power or water power, or by an engine or other artificial power source. The charge/discharge control portion 21 may for example be connected to a commercial power supply in place of the electric generation device 22.

The load device 23 may be various kinds of loads driven by electric power supplied from the battery power supply device 1, and may for example be a motor, or load equipment for backup.

The charge/discharge control portion 21 charges the battery blocks BB1 to BBm of the battery power supply device 1 with excess power from the electric generation device 22 or with regenerated power generated by the load device 23. Further, if the current consumption of the load device 23 increases sharply, or the generation quantity of the electric generation device 22 falls and the electric power required by the load device 23 exceeds the output of the electric generation device 22, the charge/discharge control portion 21 supplies the power deficiency from the battery blocks BB1 to BBm of the battery power supply device 1 to the load device 23.

Further, the charge/discharge control portion 21 receives the SOC1 to SOCm and full charge capacities FCC1 to FCCm from the notification portion 106 via the communication portions 11, 24. And, charging and discharging of the battery blocks BB1 to BBm are controlled such that for example the SOC1 to SOCm of the battery blocks BB1 to BBm are maintained within a prescribed range, set in advance.

Next, operation of a battery power supply system 3 configured as described above is explained. FIG. 2 is a flowchart showing an example of operations to calculate the number of effective batteries EN of the battery power supply device 1 shown in FIG. 1. First, in step S1 the total current detection portion AA detects the total current value I_{AA} (step S1), and 1 is substituted into the variable i indicating the number of the battery block BB (step S2).

Then, the first separate current value I_{Axi} is detected by the first separate current detection portion Axi in the ith battery block BB (step S3). And, the first separate current value I_{Axi} is compared with a threshold value Iz by the effective battery number estimation portion 101 (step S4). Here the threshold value Iz is a judgment threshold value used to judge whether the first separate current value I_{Axi} is effectively zero. As the threshold value Iz, for example a value obtained by adding a margin to the current detection error by the first separate current detection portion Axi may be set in advance.

And, if the first separate current value I_{Axi} exceeds the threshold value Iz, that is, if the first separate current value I_{Axi} is not zero (YES in step S4), the first separate current value I_{Axi} is set as the separate current value I_{Ai} by the effective battery number estimation portion 101 (step S5).

On the other hand, if the first separate current value I_{Axi} is equal to or less than the threshold value Iz, that is, if the first separate current value I_{Axi} is effectively zero (NO in step S4), then it is possible that the fuse Fi-1 has undergone cutoff and current is not flowing in the secondary battery Bi-1. In this case, the number of effective batteries ENi cannot be estimated based on the first separate current value I_{Axi}.

Hence the second separate current value I_{Ayi} is detected by the second separate current detection portion Ayi in the ith battery block BB (step S6). And, the second separate current value I_{Ayi} is set as the separate current value I_{Ai} by the effective battery number estimation portion 101 (step S7).

By this means, even when the fuse Fi-1 series-connected to the first separate current detection portion Axi is cut off, the number of effective batteries ENi in the ith battery block BB can be estimated.

Next, the effective battery number estimation portion 101 divides total current value I_{AA} by the separate current value I_{Ai}, and for example rounds to the fourth place below the decimal point, to calculate the number of effective batteries ENi in the ith battery block BB (step S8). That is, the total current value I_{AA} of current flowing in the battery block BBi is distributed into each of the secondary batteries Bi the fuses F of which have not undergone cutoff, and one of these distributed current values is the separate current value I_{Ai}. Hence by dividing the total current value I_{AA} by the separate current value I_{Ai}, the number of effective batteries ENi can be calculated.

Further, the effective battery number estimation portion 101 stores the number of effective batteries ENi obtained in this way in the storage portion 107.

Next, the effective battery number estimation portion 101 compares the variable i with the number of battery blocks m, and if the variable i is less than the number of battery blocks m (NO in step S9), 1 is added to the variable i by the effective battery number estimation portion 101 in order to calculate the number of effective batteries ENi for the next battery block BB (step S10), and steps S3 to S9 are again repeated.

And, if the variable i is equal to or greater than the number of battery blocks m (YES in step S9), then the effective battery quantities EN1 to ENm have been calculated for all the battery blocks BB, and so by again repeating steps S1 to S9, the effective battery quantities EN1 to ENm are always updated to the latest state.

It is not necessary to provide second separate current detection portions Ay, and only first separate current detection portions Ax may be used, with steps S4, S6 and S7 omitted. However, if the second separate current detection portions Ay are comprised and steps S4, S6 and S7 are executed, then even in cases when the fuse F series-connected to a first separate current detection portion Ax is cut off, the number of effective batteries can be calculated, which is more desirable.

Further, an example was presented in which two separate current detection portions are comprised in each battery block, but three or more separate current detection portions may be comprised, and when the current value detected by one separate current detection portion is effectively zero, the current value detected by another separate current detection portion may be used.

Further, an effective battery number detection portion need not be configured using a total current detection portion AA, first separate current detection portions Axi, second separate current detection portions Ayi, and an effective battery number estimation portion 101.

For example, as in the battery power supply device 1a (battery power supply system 3a) shown in FIG. 5, instead of the first separate current detection portions Ax1 to Axm, second separate current detection portions Ay1 to Aym, and effective battery number estimation portion 101, a configuration may be employed comprising voltage detection portions VS1 to VSm, an internal resistance detection portion 108, and an effective battery number estimation portion 101a as an example of an effective battery number detection portion. The battery power supply device 1a otherwise is configured and operates similarly to the battery power supply device 1.

The battery power supply device 1a detects the internal resistance of a battery block BB in which a plurality of secondary batteries B are parallel-connected, for example, by means of an internal resistance detection portion 108. And, when a fuse F undergoes cutoff, the internal resistance increases, and so the effective battery number estimation portion 101a may calculate the number of effective batteries based on the amount of change in the internal resistance.

For example, the internal resistance value of a battery block BB and the number of effective batteries EN corresponding to the internal resistance value may be stored in advance in association in a LUT in ROM, and by referencing the LUT, the effective battery number estimation portion 101a may acquire the number of effective batteries EN associated with the detected internal resistance value.

Each of the internal resistance values R1 to Rm of the battery blocks BB1 to BBm can for example be detected as follows. The internal resistance values R1 to Rm are equivalent to an example of present resistance values.

The voltage detection portions VS1 to VSm detect the terminal voltages Vt1 to Vtm of each of the battery blocks BB1 to BBm. The internal resistance detection portion 108 detects the internal resistance values R1 to Rm from the terminal voltages Vt1 to Vtm and the total current value I_{AA}.

And, when the internal resistance detection portion 108 detects the internal resistance value Ri of a battery block BBi, a plurality of sets of the terminal voltage Vti of the battery block BBi and the total current value I_{AA} are acquired, and the slope of the regression line obtained from the plurality of sets is estimated to be the internal resistance value Ri for the battery block BBi.

FIG. 3 is an explanatory diagram used to explain an example of a method of detecting the internal resistance value Ri by this internal resistance detection portion 108.

The internal resistance detection portion 108 acquires a plurality of sets of terminal voltage values Vti and total current values I_{AA} and generates a regression line. FIG. 3 shows an example in which data P1 for which the total current value I_{AA} is I1 and the terminal voltage value Vti is V1, data P2 for which the total current value I_{AA} is I2 and the terminal voltage value Vti is V2, and data P3 for which the total current value I_{AA} is I3 and the terminal voltage value Vti is V3, are acquired, and from the data P1, P2, P3, a regression line L is generated.

The regression line L obtained in this way is represented by equation (5) below; the coefficient R expressing the line slope is obtained as the internal resistance value Ri of the battery block BBi.

Vti=Ri×I_{AA}+V₀ (5)

In order to obtain the regression line L, sets of a plurality of terminal voltage values Vti with different values and total current values I_{AA} must be acquired. However, in for example an electric vehicle, charge/discharge currents vary in a complex manner according to vehicle acceleration and deceleration, the state of the road surface, and similar, and for example in wind power electric generation, charge/discharge currents vary in a complex manner according to changes in wind speed. Hence it is possible to acquires sets of a plurality of terminal voltage values Vti with different values and total current values I_{AA} necessary to obtain a regression line L in an interval of, for example, approximately one minute.

There is a correlation between the internal resistance value R of battery blocks BB and the temperature t of the battery blocks BB. Hence the internal resistance value R may also be estimated by storing a table of internal resistances indicating the relation between the temperature and internal resistance value of battery blocks BB in advance in ROM or similar, and having the internal resistance detection portion 108 use the internal resistance table to convert a temperature t detected by the temperature sensor 18 into the internal resistance value R for the battery blocks BB.

In addition, various other well-known methods can be used as methods to detect the internal resistance value of battery blocks BB.

Here, in for example a battery block BB the internal resistance value of which is Ri, for example, the amount of change in the internal resistance value when one secondary battery B among n parallel-connected batteries is detached due to cutoff of a fuse F is smaller than Ri/n.

In contrast, by means of an effective battery number detection portion configured using the total current detection portion AA, first separate current detection portions Axi, second separate current detection portions Ayi, and effective battery number estimation portion 101 shown in FIG. 1, the change amounts in the first separate current value I_{Axi} or second separate current value I_{Ayi} when one secondary battery B among n parallel-connected secondary batteries is detached due to cutoff of a fuse F are respectively I_{Axi}/n and I_{Ayi}/n. Hence the change amount of the detection value obtained for the cut-off number of batteries is larger than when detection is based on the internal resistance value, and as a result the precision of calculation of the number of effective batteries ENi based on this change amount is improved compared with the calculation precision based on the internal resistance, and in this respect is more desirable.

Next, operation by the battery power supply device 1 shown in FIG. 1 to calculate the SOC1 to SOCm and full charge capacities FCC1 to FCCm is explained. FIG. 4 is a flowchart showing an example of operation by the charge state detection circuit 4 in FIG. 1 to calculate the SOC1 to SOCm and the full charge capacities FCC1 to FCCm. The steps S11 to S24 shown in FIG. 4 are executed in parallel with the steps S1 to S10 shown in FIG. 2.

First, the effective battery quantities EN1 to ENm calculated in step S8 are respectively substituted into variables PEN1 to PENm to detect changes in the effective battery quantities (step S11). Further, 1 is substituted into the variable i indicating the number of the battery block BB (step S12).

Next, the total current value I_{AA} is detected by the total current detection portion AA, and the temperature t is detected by the temperature sensor 18 (step S13). And, the degradation state detection portion 102 divides the total current value I_{AA} by the number of effective batteries ENi, and calculates the charge/discharge current Ii flowing in one of the secondary batteries B included in the battery block BBi (step S14).

Next, the degradation state detection portion 102 counts the number of charge/discharge cycles CYC (step S15).

Next, the degradation state detection portion 102 references a LUT stored for example in ROM. And, the degradation state detection portion 102 acquires, as the degradation rate Dri, the degradation rate stored in the LUT in association with the number of charge/discharge cycles CYC, charge/discharge current value Ii, and temperature t (step S16). Further, the degradation state detection portion 102 stores the degradation rate Dri obtained in this way, in association with the number i, in the storage portion 107.

Next, equation (1) is used by the capacity information generation portion 103 to calculate the full charge capacity FCCi (actual full charge capacity) of the battery block BBi (step S17). And, the capacity information generation portion 103 stores the full charge capacity FCCi obtained in this way, in association with the number i, in the storage portion 107. The capacity information generation portion 103 may, instead of the full charge capacity FCCi in step S17, calculate the SOHi as the capacity information, and store this in association with the number i in the storage portion 107.

Next, the electricity quantity calculation portion 104 calculates the stored electricity quantity Qi, which is the electricity quantity charging the battery block BBi, by integrating the total current value I_{AA}, for example over each time unit (step S18).

Next, the electricity quantity calculation portion 104 compares the latest the number of effective batteries ENi, updated in step S8, and the variable PENi indicating the previous the number of effective batteries ENi (step S19). And, if the number of effective batteries ENi is equal to or greater than the variable PENi (NO in step S19), the number of effective batteries ENi for the battery block BBi is not reduced, and so the stored electricity quantity Qi is maintained unchanged, and processing proceeds to step S21.

If on the other hand the number of effective batteries ENi is less than the variable PENi (YES in step S19), then the number of effective batteries ENi of the battery block BBi is reduced, and so the electricity quantity calculation portion 104 updates the stored electricity quantity Qi to the stored electricity quantity Qi multiplied by ENi/PENi (step S20), and processing then proceeds to step S21.

Next, the charge state detection portion 105 uses equation (4) to calculate the SOCi (step S21). Further, the charge state detection portion 105 stores the SOCi obtained in this way, in association with the number i, in the storage portion 107. And, the charge state detection portion 105 compares the variable i with the number m of battery blocks BB (step S22), and if the variable i is less than the number m (NO in step S22), 1 is added to the variable i (step S23), and the steps S13 to S22 are again repeated.

If on the other hand the variable i is equal to or greater than the number m (YES in step S22), then the full charge capacities FCC1 to FCCm and values of SOC1 to SOCm have all been acquired, and so processing proceeds to step S24.

And, in step S24, the notification portion 106 transmits the full charge capacities FCC1 to FCCm and the values of SOC1 to SOCm to the external device 2. Then, the charge/discharge control portion 21 receives the full charge capacities FCC1 to FCCm and the values of SOC1 to SOCm, and based on the full charge capacities FCC1 to FCCm and the values of SOC1 to SOCm, can control charging and discharging of the battery blocks BB1 to BBm.

In the above, a portion of the secondary batteries B are detached from a battery block BB due to cutoff of a fuse F included in the battery block BB. And, by detachment of a portion of the secondary batteries B from the battery block BB, even in cases where the characteristics of the battery block BB have changed, through the processing of steps S1 to S24, the battery power supply device 1 can ascertain the full charge capacity FCC and the SOC of the battery block BB, and can notify an external device 2.

In the external device 2, based on the full charge capacity FCC and the SOC of the battery block BB after a fuse F has undergone cutoff and characteristics have changed, charging and discharging of the battery block BB can be controlled, so that a battery block BB in which a fuse F has undergone cutoff and a portion of the secondary batteries B has been detached can easily be continued to be used.

The capacity information generation portion 103 may calculate the SOHi as capacity information in step S17, and the charge state detection portion 105 may use the FCCi calculated in step S21 using equation (2) to calculate the SOCi.

Further, a configuration may be employed in which a degradation state detection portion 102 and temperature sensor 18 are not comprised, steps S14, S15 and S16 are not executed, and in step S17 the degradation rate Dri is not used.

Further, in step S24 the notification portion 106 causes information stored in the storage portion 107, such as for example the degradation rates Dr1 to Drm, the effective battery quantities EN1 to ENm, the full charge capacities FCC1 to FCCm (or SOH1 to SOHm), and the values of SOC1 to SOCm, in association with the number i which is identification information, to be displayed by the display portion 19. Further, the notification portion 106, by transmitting this information to the display portion 28 via the communication portions 11, 24, causes this information to be displayed, in association with the number i, by the display portion 28.

Further, as the communication portion 11, for example a communication interface which can be connected to the Internet or another communication network, or a USB (Universal Serial Bus) or other communication interface, is used. The notification portion 106 may transmit information stored in the storage portion 107 to a remote server device connected to a network, or to a battery information monitoring device connected to a USB or other communication interface, or similar.

Further, when for example an operating switch, not shown, is operated, or when for example a display request or transmission request for information stored in the storage portion 107 is received from outside by the communication portion 11, the notification portion 106 may cause information stored in the storage portion 107 to be transmitted to the outside by the communication portion 11 or to be displayed by the display portions 19, 28.

There are cases in which, after being used in battery power supply systems 3 or 3a, the battery blocks BB1 to BBm are reused, as for example being put on the market as used products. In such a market for used products, the lesser the characteristic degradation and the larger the full charge capacity, the higher is the value of a battery block. And, a battery block with higher value will be sold at a higher price than a battery block with lower value.

And higher values of the degradation rates Dr1 to Drm, effective battery quantities EN1 to ENm, full charge capacities FCC1 to FCCm, SOH1 to SOHm, and SOC1 to SOCm mean higher values for battery blocks, so that by displaying these information items or causing them to be transmitted to the outside, for example an enterprise engaging in reuse can easily reuse battery blocks BB1 to BBm.

Further, the storage portion 107 is configured using a nonvolatile storage element, so that even after a reuse enterprise or similar has removed the battery blocks BB1 to BBm from the battery power supply device 1 or 1a, the degradation rates Dr1 to Drm, effective battery quantities EN1 to ENm, full charge capacities FCC1 to FCCm, SOH1 to SOHm, and SOC1 to SOCm stored in the storage portion 107 are not erased.

Hence even after a reuse enterprise or similar has removed the battery blocks BB1 to BBm from the battery power supply device 1 or 1a, by supplying a power supply voltage from outside to the charge state detection circuit 4 or 4a, information stored in the storage portion 107 can be transmitted by the notification portion 106, so that convenience is improved.

The storage portion 107 may also be a volatile storage element. Even if the storage portion 107 is a volatile storage element, information stored in the storage portion 107 can be transmitted by the notification portion 106, so long as this is performed prior to removing the battery blocks BB1 to BBm from the battery power supply device 1 or 1a.

Further, these information items are displayed or transmitted together with the number i which is identification information for the battery blocks BB1 to BBm, and moreover the number i is displayed on the surfaces of the battery blocks BB1 to BBm, so that a reuse enterprise can easily identify the value of each of the battery blocks BB1 to BBm. If the value of each of the battery blocks BB1 to BBm can each be identified, by combining battery blocks having approximately the same value, new battery modules can be configured, and valuation can easily be performed according to the value in battery module units.

The battery power supply systems 3, 3a may comprise either one among the display portions 19 and 28, or need not comprise either display portion 19 and 28. Further, the notification portion 106 need not transmit information stored in the storage portion 107.

### Second Embodiment

Next, a battery power supply device 1b comprising the charge state detection circuit 4b and a battery information monitoring device 5 of a second embodiment of the invention are explained. FIG. 6 is a block diagram showing one example of the configuration of the battery power supply device 1b and battery information monitoring device 5 of the second embodiment.

The battery power supply device 1b shown in FIG. 6 differs from the battery power supply device 1 shown in FIG. 1 in the following respects. That is, the battery power supply device 1b, similarly to the battery power supply device 1a shown in FIG. 5, comprises voltage detection portions VS1 to VSm and an internal resistance detection portion 108. The control portion 10b of the battery power supply device 1b also functions as an indicator value calculation portion 109 and ranking portion 110. Further, the notification portion 106b is also different in that, in addition to operations similar to those of the notification portion 106, value information is broadcast.

The battery power supply device 1b is combined with an external device 2, not shown, to configure a battery power supply system.

Further, a communication cable 6 can be detachably connected to the connection terminal 17. And, by connecting the communication table 6 between the battery power supply device 1b and the battery information monitoring device 5, communication between the battery power supply device 1b and battery information monitoring device 5 becomes possible.

Otherwise the configuration and operation are similar to those of the battery power supply devices 1 and 1a shown in FIG. 1 and FIG. 5, and so explanations are omitted; in the following, characteristic portions of the battery power supply device 1b are explained.

The notification portion 106b uses the values of SOH1 to SOHm calculated by the capacity information generation portion 103 as value indicators (first value indicators). In this case, the capacity information generation portion 103 is equivalent to an example of an indicator value calculation portion.

Further, the values of SOH1 to SOHm indicate the ratios of the present (actual) full charge capacities to the initial full charge capacities of the battery blocks BBi. Below, an SOHi value indicating the ratio of the present (actual) full charge capacity to the initial full charge capacity of a battery block BBi is called the SOHi(C) (i: 1 to m).

Further, the internal resistance values of the battery blocks BB1 to BBm in the initial state when all fuses F are in the conducting state are stored in advance in ROM, for example, as the initial internal resistance values Rs1 to Rsm. The initial internal resistance values Rs1 to Rsm are normally equal, and so an initial internal resistance value Rs representing the initial internal resistance values Rs1 to Rsm may be stored in ROM or similar.

The indicator value calculation portion 109 calculates SOHi(R) (i: 1 to m) as value indicators (second value indicators) of the battery blocks BBi, based on the internal resistance values R1 to Rm detected by the internal resistance detection portion 108, the initial internal resistance values Rs1 to Rsm, and equation (6) below.

SOHi(R)=Rsi/Ri (6)

SOHi(C) and SOHi(R) were presented as examples of value indicators, but a value indicator may be any quantity which indicates the value of a battery block BBi, and is not limited to SOHi(C) and SOHi(R).

The ranking portion 110 ranks the value of the battery blocks BB1 to BBm based on SOH1(C) to SOHm(C), and takes the results to be first rank information RK1(C) to RKm(C).

Further, the ranking portion 110 ranks the value of the battery blocks BB1 to BBm based on SOH1(R) to SOHm(R), and takes the results to be second rank information RK1(R) to RKm(R).

Specifically, for example, the ranking portion 110 takes the first rank information RKi(C) to be rank A when 1≧SOHi(C)>0.7, takes the first rank information RKi(C) to be rank B when 0.7≧SOHi(C)>0.3, and takes the first rank information RKi(C) to be rank C when 0.3≧SOHi(R).

Similarly, for example, the ranking portion 110 takes the second rank information RKi(R) to be rank A when 1≧SOHi(R)>0.7, takes the second rank information RKi(R) to be rank B when 0.7≧SOHi(R)>0.3, and takes the second rank information RKi(R) to be rank C when 0.3≧SOHi(R).

The ranking portion 110 for example stores the first rank information RK1(C) to RKm(C) and second rank information RK1(R) to RKm(R), in association with the number i, in the storage portion 107. The ranking portion 110 need not necessarily store this information in the storage portion 107.

The notification portion 106b reads out the first rank information RK1(C) to RKm(C) and second rank information RK1(R) to RKm(R) from for example the storage portion 107 and causes this information to be displayed as value information, in association with the number i, by the display portion 19, either with arbitrary timing, or when an operating switch has been operated, or when for example a request to display or to transmit value information has been received from outside by the communication portion 11. Further, the notification portion 106b, by causing this value information to be transmitted to the display portion 28 by the communication portions 11 and 24, may cause this information to be displayed in association with the number i by the display portion 28. Further, the notification portion 106b may transmit this value information, in association with the number i, to the battery information monitoring device 5 by means of the communication portion 11 and communication cable 6.

The notification portion 106b may also cause the above-described display, or notification by transmission, of any one among the first rank information RK1(C) to RKm(C) and second rank information RK1(R) to RKm(R) as value information.

The battery information monitoring device 5 comprises a control portion 50, display portion 52, communication portion 53, and connector 54. The connector 54 is connected to the communication portion 53. When the communication cable 6 is connected to the connector 54, the communication portion 11 and communication portion 53 are connected via the communication cable 6, and communication between the battery power supply device 1b and the battery information monitoring device 5 becomes possible.

The communication portion 53 may for example be a USB communication interface, or may be an Internet communication interface. Further, the battery information monitoring device 5 may for example be a portable personal computer, or may be a server device connected to a network.

The display portion 52 may for example be a liquid crystal display or other display device.

The control portion 50 is configured comprising, for example, a CPU which executes prescribed computation processing, ROM which is a storage portion in which a prescribed control program is stored, RAM which is a storage portion for temporarily storing data, and peripheral circuitry and similar. The control portion 50, by executing a control program stored for example in ROM, functions as a ranking portion 501.

Upon receiving first rank information RK1(C) to RKm(C) and second rank information RK1(R) to RKm(R) by means of the communication portion 53, the control portion 50 causes this information to be displayed, in association with the number i, by the display portion 52.

The control portion 10b need not comprise a ranking portion 110, and the notification portion 106b may display, or communicate by transmission, SOH1(C) to SOHm(C) and SOH1(R) to SOHm(R) as value information.

In this case, the ranking portion 501 generates the first rank information RK1(C) to RKm(C) and second rank information RK1(R) to RKm(R) by operation similar to that of the above-described ranking portion 110, based on the SOH1(C) to SOHm(C) and SOH1(R) to SOHm(R) received from the communication portion 53. And, the ranking portion 501 causes this information to be displayed in association with the number i by the display portion 52.

The notification portion 106b may perform the above-described display or communication by transmission of any one among the SOH1(C) to SOHm(C) and SOH1(R) to SOHm(R) as value information, and based on value information communicated from the notification portion 106b, the ranking portion 501 may generated any among the first rank information RK1(C) to RKm(C) and second rank information RK1(R) to RKm(R).

In the above, by means of the battery power supply device 1b and battery information monitoring device 5 shown in FIG. 6, first rank information RK1(C) to RKm(C) and second rank information RK1(R) to RKm(R), which divide into ranks the value of the battery blocks BB1 to BBm, can be displayed in association with the number i by any one among the display portions 19, 28 and 52, so that, for example, a reuse enterprise or similar can easily perform valuation of the battery blocks BB1 to BBm based on the first rank information RK1(C) to RKm(C) and second rank information RK1(R) to RKm(R).

In this case, the first rank information RK1(C) to RKm(C) is suitable as an indicator of value when for example the battery blocks BB1 to BBm are used in high-power storage applications, such as for example storage devices for load leveling. Further, the second rank information RK1(R) to RKm(R) is suitable as an indicator of value when the battery blocks BB1 to BBm are used in applications such as for example HEVs, EVs and similar, where instantaneous output of high power is required.

Further, the charge state detection circuit 4b need not comprise a ranking portion 110; even in cases where the notification portion 106b performs the above-described display or communication by transmission of the SOH1(C) to SOHm(C) and SOH1(R) to SOHm(R) as value information, the SOH1(C) to SOHm(C) is suitable as an indicator of value when for example using the battery blocks BB1 to BBm as storage devices for power adjustment. Further, the SOH1(R) to SOHm(R) is suitable as an indicator of value when for using the battery blocks BB1 to BBm in applications where instantaneous output of high power is required.

Further, the charge state detection circuit 4b may employ a configuration in which, similarly to the charge state detection circuit 4a shown in FIG. 5, separate current detection portions Ax and separate current detection portions Ay are not comprised, and instead of an effective battery number estimation portion 101, an effective battery number estimation portion 101a is used.

That is, the charge state detection circuit according to one aspect of the invention is a charge state detection circuit, which detects a state of charge of a battery block in which are parallel-connected a plurality of series circuits of a secondary battery and a cutoff element which assumes a cutoff state of cutting off the charge/discharge path of the secondary battery and a conducting state different from the cutoff state, the charge state detection circuit comprising: an effective battery number detection portion which detects, as the number of effective batteries, the number of cutoff elements in the conducting state from among the plurality of cutoff elements included in the battery block; a capacity information generation portion which, based on the number of effective batteries, generates capacity information related to actual full charge capacity, which is the actual full charge capacity of the battery block; a total current detection portion, which detects as a total current value a current flowing in the entire battery block; an electricity quantity calculation portion, which calculates, as a stored electricity quantity, an electricity quantity stored in the battery block, by integrating the total current value; and a charge state detection portion, which, based on the capacity information and the stored electricity quantity, detects a state of charge, which is a ratio of the stored electricity quantity to the actual full charge capacity.

By means of this configuration, if a portion of the plurality of secondary batteries included in the battery block are detached from the circuit by cutoff of the cutoff element, the number of effective batteries detected by the effective battery number detection portion is reduced. And, based on this the number of effective batteries, the capacity information generation portion generates capacity information relating to the actual full charge capacity, which is the actual full charge capacity of the battery block. Further, the electricity quantity calculation portion integrates the current flowing in the battery block, and calculates the stored electricity quantity charging the battery block. And, the charge state detection portion detects the state of charge, which is the ratio of this stored electricity quantity to the full charge capacity, based on the full charge capacity indicated by the capacity information and the stored electricity quantity.

In this case, when a portion of the secondary batteries included in the battery block is cut off, the number of effective batteries is reduced, and a state of charge which reflects this reduction in the number of effective batteries is detected, so that even when a portion of the secondary batteries included in the battery block is cut off, the state of charge of the battery block can be ascertained.

Further, the capacity information generation portion may define the full charge capacity of the battery block in an initial state, when all of the cutoff elements included in the battery block are in the conducting state, as an initial full charge capacity, and define a ratio of the number of effective batteries to the number of the series circuits included in the battery block as an effective battery ratio, thereby generating a product of the initial full charge capacity and the effective battery ratio as capacity information indicating the actual full charge capacity.

By means of this configuration, when a portion of the secondary batteries included in a battery block is cut off, the charge capacity obtained from the remaining secondary batteries is obtained as capacity information indicating the actual full charge capacity, which is the full charge capacity of the battery block.

Further, the capacity information generation portion may generate, as the capacity information, an effective battery ratio, which is a ratio of the number of effective batteries to the number of the series circuits included in the battery block; and the charge state detection portion may define a full charge capacity of the battery block when all of the cutoff elements included in the battery block are in the conducting state as an initial full charge capacity, and acquires, as the actual full charge capacity, a product of the initial full charge capacity and the effective battery ratio which is the capacity information.

The effective battery ratio, which is the ratio of the number of effective batteries to the number of series circuits included in one battery block, is substantially equivalent to the SOH (State of Health), which is the ratio of the present full charge capacity to the initial full charge capacity of the battery block. Hence by means of this configuration, this SOH is generated as capacity information by the capacity information generation portion. And, the charge state detection portion can acquire the actual full charge capacity, which is the present full charge capacity, by taking the product of this SOH and the initial full charge capacity of the battery block.

Further, it is preferable that a degradation state detection portion which detects degradation information indicating the degradation state of the plurality of secondary batteries be further comprised, and that the capacity information generation portion generate capacity information based on the degradation information and the number of effective batteries.

The full charge capacity of a secondary battery decreases as degradation advances. Hence by means of this configuration, degradation information indicating the degradation state of secondary batteries is detected by the degradation state detection portion. And, capacity information is generated by the capacity information generation portion based on this degradation information and the number of effective batteries, so that the effect of degradation is reflected in the capacity information, and as a result the precision of the capacity information is improved.

Further, it is preferable that the degradation state detection portion acquire a degradation ratio, which is the ratio of the full charge capacity after degradation to the full charge capacity in the initial state for one of the plurality of secondary batteries, as the degradation information; and that the capacity information generation portion define the full charge capacity of the battery block when all the cutoff elements included in the battery block are in the conducting state as an initial full charge capacity, define the ratio of the number of effective batteries to the number of series circuits included in the battery block as the effective battery ratio, thereby generating the product of the initial full charge ratio, the effective battery ratio, and the degradation rate as capacity information indicating the actual full charge capacity.

By means of this configuration, when a portion of the secondary batteries included in the battery block is cut off, the charge capacity obtained from the remaining secondary batteries is obtained as capacity information indicating the full charge capacity of the battery block, in a state which reflects the reduction in capacity due to secondary battery degradation.

Further, the degradation state detection portion may acquire, as the degradation information, a degradation ratio which is the ratio of the full charge capacity after degradation to the full charge capacity in the initial state of one of the plurality of secondary batteries; the capacity information generation portion may define the ratio of the number of effective batteries to the number of series circuits included in the battery block as the effective battery ratio, and generate the product of the effective battery ratio and the degradation rate as the capacity information; and the charge state detection portion may define the full charge capacity of the battery block when all the cutoff elements included in the battery block are in the conducting state as the initial full charge capacity, and may acquire, as the actual full charge capacity, the product of the initial full charge capacity and a ratio indicated by the capacity information.

The ratio obtained by multiplying the effective battery ratio and the degradation rate is equivalent to an SOH with higher precision than when degradation information is not taken into consideration. Hence by means of this configuration, an SOH with improved precision is generated as capacity information by the capacity information generation portion. And, by taking the product of this SOH and the initial full charge capacity of the battery block, the charge state detection portion can acquire the present full charge capacity, so that the precision of acquisition of the full charge capacity is improved.

Further, it is preferable that, when the number of effective batteries detected by the effective battery number detection portion is reduced, the electricity quantity calculation portion calculates the product of the stored electricity quantity and the ratio of the number of effective batteries after the reduction to the number of effective batteries before the reduction, as a new stored electricity quantity.

When a portion of the secondary batteries included in a battery block is detached and the number of effective batteries is reduced, not only is the full charge capacity reduced, but the stored electricity quantity charging the battery block which can be used is also reduced. Hence by means of this configuration, when the number of effective batteries is reduced, the electricity quantity calculation portion can multiply the stored electricity quantity and the ratio of the number of effective batteries before the reduction to the number of effective batteries after the reduction, to calculate the new stored electricity quantity.

Further, it is preferable that an internal resistance detection portion which detects the internal resistance of the battery block be further comprised, and that based on the internal resistance detected by the internal resistance detection portion, the effective battery number detection portion acquire the number of effective batteries such that the larger the internal resistance value, the fewer is the number of effective batteries.

By means of this configuration, the internal resistance of the battery block is detected by the internal resistance detection portion. The smaller the number of effective batteries, the larger is the internal resistance value of the battery block. Based on the internal resistance detected by the internal resistance detection portion, the effective battery number detection portion can detect the number of effective batteries such that the larger the internal resistance value, the smaller is the number of effective batteries.

Further, the effective battery number detection portion may comprise an separate current detection portion which detects a separate current value, representing the current flowing through one of the plurality of secondary batteries included in the battery block, and an effective battery number estimation portion, which calculates the number of effective batteries by dividing the total current value by the separate current value.

By means of this configuration, the current flowing in one among the plurality of secondary batteries included in the battery block is detected as a separate current value by the separate current detection portion. And, this separate current value is a result of distribution of the total current detected by the total current detection portion among the effective secondary batteries, which are not cut off. Hence with a portion of the cutoff elements undergoing cutoff and the number of effective batteries being decreased, the separate current value is increased, whereby the effective battery number estimation portion can estimate the number of effective batteries based on the total current value and the separate current value.

Further, it is preferable that each of the cutoff elements be a protective element which undergoes cutoff in a case where an abnormality occurs in the secondary battery with which the cutoff element is series-connected.

By means of this configuration, each of the secondary batteries can be made independent from the other secondary batteries and detached from the circuit by the protective elements, so that while detaching a secondary battery in which an abnormality has occurred from the battery block, use of the remaining secondary batteries can be continued.

Further, it is preferable that a storage portion, which stores at least one among degradation information indicating the degradation state of the secondary batteries, information indicating the number of effective batteries, and information indicating the state of charge, and a notification portion which communicates information stored in the storage portion, be further comprised.

Degradation information indicating the degradation state of the secondary batteries, information indicating the number of effective batteries, capacity information, and information indicating the state of charge, are correlated with the value of the battery block. By means of this configuration, information correlated with the value of the battery block is stored in the storage portion, and is communicated by the notification portion. Hence users and workers can evaluate the value of the battery block.

Further, it is preferable that an indicator value calculation portion which calculates a value indicator, which is an indicator representing the value of the battery block, and a notification portion which communicates value information which is information relating to the value indicator, be further comprised.

By means of this configuration, the value of a battery block is indicated as a value indicator, and is communicated. Hence users and workers can quantitatively evaluate the value of the battery block.

Further, it is preferable that the indicator value calculation portion define the full charge capacity of the battery block in the initial state, at the time at which all of the cutoff elements included in the battery block are in the conducting state, as the initial full charge capacity, and calculate the ratio of the actual full charge capacity to the initial full charge capacity as the value indicator.

By means of this configuration, based on the present full charge capacity of the battery block, the value of the battery block is indicated as a value indicator. This value indicator is suitable as an indicator of the value of the battery block when for example using the battery block in high-power storage applications, such as storage devices for load leveling applications.

Further, an internal resistance detection portion which detects the internal resistance of the battery block as the present resistance may be further comprised, and the indicator value calculation portion may define the internal resistance value of the battery block in the initial state in which all of the cutoff elements included in the battery block are in the conducting state as the initial internal resistance, and may calculate the ratio of the present resistance value to the initial internal resistance value as the value indicator.

By means of this configuration, based on the internal resistance of the battery block, the value of the battery block is indicated as a value indicator. Such a value indicator is suitable as an indicator of the value of the battery block when for example applying the battery block in applications such as for example HEVs, EVs and similar, where instantaneous output of high power is required.

Further, it is preferable that a ranking portion which ranks the value of the battery block based on the value indicator be further comprised, and that the notification portion communicate the value rank assigned by the ranking portion as value information.

By means of this configuration, value information is ranked and communicated, so that users and workers can easily perform rough evaluation of the value of a battery block. By this means, for example in cases where a user or worker is to combine battery blocks having approximately the same value to configure a battery module, or in similar cases, by combining battery blocks with the same rank, such a battery module can easily be configured.

Further, it is preferable that a plurality of such battery blocks be series-connected; that the effective battery number detection portion detect the number of effective batteries for each of the battery blocks; that, based on the number of effective batteries for each battery block, the capacity information generation portion generate the capacity information for each of the battery blocks; that the electricity quantity calculation portion calculate the stored electricity quantity for each of the battery blocks; and that the charge state detection portion detect the state of charge of each of the battery blocks based on the capacity information for each battery block and the stored electricity quantity for each battery block.

By means of this configuration, even when a plurality of battery blocks are series-connected, the state of charge of each battery block can be detected.

Further, it is preferable that a plurality of such battery blocks be series-connected; that identification information identifying each of the battery blocks be imparted to each of the battery blocks; that the effective battery number detection portion detect the number of effective batteries for each of the battery blocks; that the capacity information generation portion generate the capacity information for each of the battery blocks based on the number of effective batteries of each of the battery blocks; that the electricity quantity calculation portion calculate the stored electricity quantity for each of the battery blocks; that the charge state detection portion detect the state of charge for each of the battery blocks, based on the capacity information for each and the stored electricity quantity for each; that the storage portion store at least one information item among degradation information indicating the degradation state of a secondary battery included in each of the battery blocks, information indicating the number of effective batteries for each of the battery blocks, capacity information for each of the battery blocks, and information indicating the state of charge of each of the battery blocks, in association with identification information for each of the battery blocks; and that the notification portion communicate information which is stored in the storage portion and related to each of the battery blocks in association with identification information associated with each of the battery blocks.

By means of this configuration, even when a plurality of battery blocks are used, information correlated to the value of each battery block is stored in a storage portion in association with identification information for each battery block, and is communicated by a notification portion. Hence a user or worker can evaluate the value of each of the battery blocks.

Further, it is preferable that a plurality of such battery blocks be series-connected; that identification information identifying each of the battery blocks be imparted to each of the battery blocks; that the indicator value calculation portion calculate the value indicator for each of the battery blocks; and that the notification portion communicate the value indicator for each of the battery blocks in association with the identification information that is associated with the battery block and the information.

By means of this configuration, even when a plurality of battery blocks are used, the value of each battery block is indicated as a value indicator, and is communicated in association with identification information for each battery block. Hence even when using a plurality of battery blocks, a user or worker can quantitatively evaluate the value of each battery block.

Further, it is preferable that a plurality of such battery blocks be series-connected; that identification information identifying each of the battery blocks be imparted to each of the battery blocks; that the indicator value calculation portion calculate the value indicator for each of the battery blocks; that the ranking portion rank the value of each of the battery blocks; and that the notification portion communicate the value information for each of the battery blocks in association with identification information that is associated with each of the battery blocks.

By means of this configuration, value information is ranked for each battery block and is communicated in association with identification information, so that even when a plurality of battery blocks are used, a user or worker can easily perform rough evaluation of the value of battery blocks. By this means, when for example a user or worker is to combine battery blocks having approximately the same value to configure a battery module, by combining battery blocks with the same rank, such a battery module can easily be configured.

Further, the battery power supply device according to one aspect of the invention comprises the above-described charge state detection circuit, and the battery block.

By means of this configuration, in a battery power supply device using a battery block in which are parallel-connected a plurality of series circuits of a secondary battery and a cutoff element to cut off the charge/discharge path of the secondary battery, when a portion of the secondary batteries included in the battery block is cut off, the number of effective batteries is reduced, and the state of charge, reflecting this reduction in the number of effective batteries, is detected, so that even when a portion of the secondary batteries included in the battery block is cut off, the state of charge of the battery block can be ascertained.

Further, the battery information monitoring device according to one aspect of the invention comprises a reception portion which receives the value information communicated from the above-described charge state detection circuit; a ranking portion, which ranks the value of the battery block based on the value information received by the reception portion; and a display portion which displays the rank of the value.

By means of this configuration, for example a user or worker can use the battery information monitoring device to rank value information for each battery block based on value information communicated from the charge state detection circuit, and can communicate the result in association with identification information, so that even when using a plurality of battery blocks, a user or worker can easily perform rough evaluation of the value of a battery block.

This application is based on Japanese Patent Application No. 2010-073279, filed on Mar. 26 2010, the contents of which are incorporated in this application.

The specific embodiments or examples presented to implement the invention are intended merely to clarify the technical content of the invention, and should be understood narrowly as limiting the invention only to these specific examples; various modifications are possible in implementation of the invention, within the scope of the gist of the invention and the claims presented below.

### INDUSTRIAL APPLICABILITY

A charge state detection circuit, a battery power supply device using such a circuit, and a battery information monitoring device of this invention can be suitably used in portable personal computers and digital cameras, portable telephone sets and other electronic equipment, electric vehicles, hybrid vehicles and other vehicles, hybrid elevators, power supply systems combining photovoltaic cells and electric generation devices with secondary batteries, and uninterruptible power supply devices and other battery-mounted devices and systems.

1. A charge state detection circuit, which detects a state of charge of a battery block in which are parallel-connected a plurality of series circuits of a secondary battery and a cutoff element which assumes a cutoff state of cutting off the charge/discharge path of the secondary battery and a conducting state different from the cutoff state,
the charge state detection circuit comprising:
an effective battery number detection portion which detects, as the number of effective batteries, the number of cutoff elements in the conducting state from among the plurality of cutoff elements included in the battery block;
a capacity information generation portion which, based on the number of effective batteries, generates capacity information related to actual full charge capacity, which is the actual full charge capacity of the battery block;
a total current detection portion, which detects as a total current value a current flowing in the entire battery block;
an electricity quantity calculation portion, which calculates, as a stored electricity quantity, an electricity quantity stored in the battery block, by integrating the total current value; and
a charge state detection portion, which, based on the capacity information and the stored electricity quantity, detects a state of charge, which is a ratio of the stored electricity quantity to the actual full charge capacity.

2. The charge state detection circuit according to claim 1, wherein the capacity information generation portion defines the full charge capacity of the battery block in an initial state, when all of the cutoff elements included in the battery block are in the conducting state, as an initial full charge capacity, and defines a ratio of the number of effective batteries to the number of the series circuits included in the battery block as an effective battery ratio, thereby generating a product of the initial full charge capacity and the effective battery ratio as capacity information indicating the actual full charge capacity.

3. The charge state detection circuit according to claim 1, wherein
the capacity information generation portion generates, as the capacity information, an effective battery ratio, which is a ratio of the number of effective batteries to the number of the series circuits included in the battery block; and
the charge state detection portion defines a full charge capacity of the battery block when all of the cutoff elements included in the battery block are in the conducting state as an initial full charge capacity, and acquires, as the actual full charge capacity, a product of the initial full charge capacity and the effective battery ratio which is the capacity information.

4. The charge state detection circuit according to claim 1, further comprising a degradation state detection portion which detects degradation information indicating a degradation state of the plurality of second batteries, wherein
the capacity information generation portion generates the capacity information based on the degradation information and the number of effective batteries.

5. The charge state detection circuit according to claim 4, wherein
the degradation state detection portion acquires, as the degradation information, a degradation ratio which is a ratio of the full charge capacity after degradation to the full charge capacity in the initial state of one of the plurality of secondary batteries; and
the capacity information generation portion defines the full charge capacity of the battery block when all of the cutoff elements included in the battery block are in the conducting state as an initial full charge capacity, and defines the ratio of the number of effective batteries to the number of the series circuits included in the battery block as an effective battery ratio, thereby generating, as capacity information indicating the actual full charge capacity, a product of the initial full charge capacity, the effective battery ratio, and the degradation ratio.

6. The charge state detection circuit according to claim 4, wherein
the degradation state detection portion acquires, as the degradation information, a degradation ratio which is a ratio of the full charge capacity after degradation to the full charge capacity in the initial state for one of the plurality of secondary batteries;
the capacity information generation portion defines a ratio of the number of effective batteries to the number of the series circuits included in the battery block as an effective battery ratio, and generates, as the capacity information, a product of the effective battery ratio and the degradation ratio; and
the charge state detection portion defines the full charge capacity of the battery block when all of the cutoff elements included in the battery block are in the conducting state as an initial full charge capacity, and acquires, as the actual full charge capacity, a product of the initial full charge capacity and a ratio indicated by the capacity information.

7. The charge state detection circuit according to claim 1, wherein, when the number of effective batteries detected by the effective battery number detection portion is reduced, the electricity quantity calculation portion calculates, as a new stored electricity quantity, a product of the ratio of the number of effective batteries after the reduction to the number of effective batteries before the reduction, and the stored electricity quantity.

8. The charge state detection circuit according to claim 1, further comprising an internal resistance detection portion which detects an internal resistance of the battery block, wherein
based on the internal resistance detected by the internal resistance detection portion, the effective battery number detection portion acquires the number of effective batteries such that the larger the internal resistance, the fewer is the number of effective batteries.

9. The charge state of detection circuit according to claim 1, wherein
the effective battery number detection portion comprises:
a separate current detection portion which detects a separate current value indicating a current flowing in one of the plurality of secondary batteries included in the battery block, and
an effective battery number estimation portion which calculates the number of effective batteries by dividing the total current by the separate current.

10. The charge state detection circuit according to claim 1, wherein each of the cutoff elements is a protective element which undergoes cutoff in a case where an abnormality occurs in a secondary battery that is series-connected to each of the cutoff elements.

11. The charge state detection circuit according to claim 1, further comprising:
a storage portion, which stores at least one of degradation information indicating a degradation state of the secondary batteries, information indicating the number of effective batteries, the capacity information, and information indicating the charge state; and
a notification portion, which communicates information stored in the storage portion.

12. The charge state detection circuit according to claim 1, further comprising:
an indicator value calculation portion, which calculates a value indicator which is an indicator representing a value of the battery block; and
a notification portion, which communicates value information which is information relating to the value indicator.

13. The charge state detection circuit according to claim 12, wherein the indicator value calculation portion defines the full charge capacity of the battery block in the initial state when all of the cutoff elements included in the battery block are in the conducting state as an initial full charge capacity, and calculates, as the value indicator, the ratio between the actual full charge capacity and the initial full charge capacity.

14. The charge state detection circuit according to claim 12, further comprising an internal resistance detection portion which detects, as a present resistance value, an internal resistance of the battery block, wherein
the indicator value calculation portion defines the internal resistance of the battery block in the initial state when all of the cutoff elements included in the battery block are in the conducting state as an initial internal resistance, and calculates, as the value indicator, the ratio between the present resistance and the initial internal resistance.

15. The charge state detection circuit according claim 12, further comprising a ranking portion which ranks a value of the battery block based on the value indicator, wherein
the notification portion communicates, as the value information, a rank of the value ranked by the ranking portion.

16. The charge state detection circuit according to claim 1, wherein
a plurality of the battery blocks are series-connected;
the effective battery number detection portion detects the number of effective batteries for each of the plurality of battery blocks;
the capacity information generation portion generates the capacity information for each of the battery blocks, based on the number of effective batteries in each of the battery blocks;
the electricity quantity calculation portion calculates the stored electricity quantity for each of the battery blocks; and
the charge state detection portion detects a state of charge for each of the battery blocks, based on the capacity information for each battery block and the stored electricity quantity for each battery block.

17. The charge state detection circuit according to claim 11, wherein
a plurality of the battery blocks are series-connected;
identification information identifying each of the battery blocks is imparted to each of the battery blocks;
the effective battery number detection portion detects the number of effective batteries for each of the plurality of battery blocks;
the capacity information generation portion generates the capacity information for each of the battery blocks, based on the number of effective batteries in each of the battery blocks;
the electricity quantity calculation portion calculates the stored electricity quantity for each of the battery blocks; and
the charge state detection portion detects a state of charge of each of the battery blocks, based on the capacity information for each battery block and the stored electricity quantity for each battery block;
the storage portion stores at least one information item, in association with identification information for each of the battery blocks, among degradation information indicating a degradation state of a secondary battery included in each of the battery blocks, information indicating the number of effective batteries for each of the battery blocks, capacity information for each of the battery blocks, and information indicating a state of charge for each of the battery blocks; and
the notification portion communicates information, which is stored in the storage portion and related to each of the battery blocks, in association with identification information associated with each of the battery blocks.

18. The charge state detection circuit according to claim 12, wherein
a plurality of the battery blocks are series-connected;
identification information identifying each of the battery blocks is imparted to each of the battery blocks;
the indicator value calculation portion calculates the value indicator for each of the battery blocks; and
the notification portion communicates the value indicator for each of the battery blocks in association with identification information that is associated with each of the battery blocks.

19. The charge state of detection circuit according to claim 15, wherein
a plurality of the battery blocks are series-connected;
identification information identifying each of the battery blocks is imparted to each of the battery blocks;
the indicator value calculation portion calculates the value indicator for each of the battery blocks;
the ranking portion ranks a value for each of the battery blocks; and
the notification portion communicates the value information for each of the battery blocks in association with identification information that is associated with each of the battery blocks.

20. A battery power supply device, comprising:
the charge state detection circuit according to claim 1; and
the battery blocks.

21. A battery information monitoring device, comprising:
a reception portion, which receives the value information communicated from the charge state detection circuit according claim 12;
a ranking portion, which ranks a value of the battery block based on value information received by the reception portion; and
a display portion, which displays a rank of the ranked value.
